(19) United States
(12) Patent Application Publication
(10) Pub. No.: US 2020/0203259 A1
(43) Pub. Date: Jun. 25, 2020

(54) INTEGRATED CIRCUIT PACKAGE

(71) Applicant: TEXAS INSTRUMENTS INCORPORATED, Dallas, TX (US)

(72) Inventor: Benjamin Allen SAMPLES, San Jose, CA (US)

(21) Appl. No.: 16/230,837

(22) Filed: Dec. 21, 2018

(51) Int. Cl. H01L 23/495; H01L 23/00; H01L 23/31; H01L 21/48

(52) U.S. Cl. CPC H01L 23/49503; H01L 23/49548; H01L 24/49; H01L 23/49579; H01L 24/73; H01L 23/3157; H01L 21/4821; H01L 24/09

(57) ABSTRACT

An integrated circuit package includes a pre-molded lead frame, a semiconductor device, and bond wires. The pre-molded lead frame includes a die attach pad, and a frame, formed of encapsulation material, that borders an edge of the die attach pad. A first lead is embedded in the frame, and includes a first end exposed at an interior surface of the frame, and a second end exposed at first exterior surface of the frame. A second lead is embedded in the frame, and includes a first end exposed at the interior surface of the frame, and a second end exposed at a second exterior surface of the frame. The second exterior surface is opposite the first exterior surface. The semiconductor device is bonded to the die attach pad. A first and second bond wires respectively couple the semiconductor device to the first end of the first and second leads.

### BACKGROUND

Some Integrated circuit (IC) packages include an IC die attached to a lead frame. The lead frame enables contacts on the die to be attached to exterior circuits. The die and portions of the lead frame may be encapsulated in a covering of epoxy or other material that protects the die and lead frame. The quad fiat non-lead package is one type of semiconductor package that includes an IC die attached to a lead frame. Electrical connections between the IC die and the lead frame are formed by bond wires. The die and the bond wires, and the lead frame are encapsulated in a molding compound. A face and terminals of the lead frame may be exposed on the exterior of the QFN package and used to attach the QFN package to a printed circuit board (PCB) or other substrate (e.g., using solder paste).

### SUMMARY

An integrated circuit package that includes a plurality of pre-molded lead frames arranged in a stack is disclosed herein. Electrical connections between the pre-molded lead frames are provided via the leads of the pre-molded lead frames. In one example, an integrated circuit package includes a pre-molded lead frame, a semiconductor device, a first bond wire, and a second bond wire. The pre-molded lead frame includes a die attach pad, a frame, a first lead, and a second lead. The frame is formed of an encapsulation material, and borders an edge of the die attach pad. The first lead is embedded in the frame, and includes a first end exposed at an interior surface of the frame, and a second end exposed at first exterior surface of the frame. The second lead is embedded in the frame, and includes a first end exposed at the interior surface of the frame, and a second end exposed at a second exterior surface of the frame. The second exterior surface is opposite the first exterior surface. The semiconductor device is bonded to the die attach pad. The first bond wire connectively couples the semiconductor device to the first end of the first lead. The second bond wire connectively coupling the semiconductor device to the first end of the second lead.

In another example, a method for fabricating a semiconductor package includes disposing a first pre-molded lead frame in a stack with a second pre-molded lead frame, and engaging an upturned lead of the first pre-molded lead frame with a downturned lead of the second pre-molded lead frame.

In a further example, an integrated circuit package, includes a first semiconductor device, a first pre-molded lead frame, a second semiconductor device, a second pre-molded lead frame, a third semiconductor device, and a third pre-molded lead frame. The first pre-molded lead frame includes a die attach pad, a frame, an upturned lead, and a downturned lead. The die attach pad is bonded to the first semiconductor device. The frame is formed of an encapsulation material, and borders an edge of the die attach pad. The upturned lead is embedded in the frame, and is conductively coupled to the first semiconductor device. The downturned lead is embedded in the frame, and is conductively coupled to the first semiconductor device. The second pre-molded lead frame is stacked with the first pre-molded lead frame, and includes a die attach pad, a frame, an upturned lead, and a downturned lead. The die attach pad of the second pre-molded lead frame is bonded to the second semiconductor device. The frame is formed of an encapsulation material, and borders an edge of the die attach pad of the second pre-molded lead frame. The upturned lead is embedded in the frame of the second pre-molded lead frame, and is conductively coupled to the second semiconductor device. The downturned lead is embedded in the frame of the second pre-molded lead frame, conductively engages the upturned lead of the first pre-molded lead frame, and is conductively coupled to the second semiconductor device. The third pre-molded lead frame is stacked with the first pre-molded lead frame and the second pre-molded lead frame. The die attach pad of the third pre-molded lead frame is bonded to the third semiconductor device. The frame is formed of an encapsulation material, and borders an edge of the die attach pad of the third pre-molded lead frame. The downturned lead is embedded in the frame of the third pre-molded lead frame, is conductively coupled to the third semiconductor device, and is conductively engaged with the upturned lead of the second pre-molded lead frame.

### BRIEF DESCRIPTION OF THE DRAWINGS

For a detailed description of various examples, reference will now be made to the accompanying drawings in which:

FIGS. 1A and 1B show perspective views of an example base pre-molded lead frame and conductive portions thereof in accordance with the present disclosure;

FIGS. 2A and 2B show perspective views of an example interior pre-molded lead frame and conductive portions thereof in accordance with the present disclosure;

FIGS. 3A and 3B show perspective views of an example cap pre-molded lead frame and conductive portions thereof in accordance with the present disclosure;

FIG. 4 shows a flow diagram for an example method for packaging a semiconductor device using stacked pre-molded lead frames in accordance with the present disclosure;

FIGS. 5A-5F show addition of a semiconductor device and bond wires to a pre-molded lead frame in accordance with the present disclosure;

FIG. 6 shows a cross-section view of a stack of pre-molded lead frames in accordance with the present disclosure;

FIGS. 7A and 7B show cross-section views of the stack of pre-molded lead frames with molding compound encasing the pre-molded lead frames in accordance with the present disclosure; and

FIGS. 8A and 8B show perspective views of the top and bottom of an integrated circuit package formed of stacked pre-molded lead frames in accordance with the present disclosure.

### DETAILED DESCRIPTION

Certain terms have been used throughout this description and claims to refer to particular system components. As one skilled in the art will appreciate, different parties may refer to a component by different names. This document does not intend to distinguish between components that differ in name but not function. In this disclosure and claims, the terms “including” and “comprising” are used in an open-ended fashion, and thus should be interpreted to mean “including, but not limited to . . . .” Also, the term “couple” or “couples” is intended to mean either an indirect or direct wired or wireless connection. Thus, if a first device couples to a second device, that connection may be through a direct connection or through an indirect connection via other devices and connections.

Semiconductor packaging technologies may include various features that facilitate complex arrangements of active and/or passive devices. For example, packaging of some semiconductor devices and circuits is made possible by intra-package multi-layer signal and power routing. Dual sided cooling enables efficient transfer of heat from one or more devices. The ability to include multiple dies and/or passive components in a package allows for fabrication of hybrid packages. Quad flat no-lead (QFN) packages do not provide for more than two layers of routing, dual-sided cooling, and/or hybrid circuitry without the inclusion of a substrate routing layer, such as a printed circuit board, which adds expense and complexity to the package.

The semiconductor packages disclosed herein include interconnection of multiple layers and provide dual-sided cooling. Components included on the layers may be active or passive. In the packages of the present disclosure, multiple pre-molded lead frames are stacked. Pre-molded lead frames include a metal (e.g., copper) die attach pad surrounded at the edges by a frame of molding compound (e.g., epoxy resin with filler and other materials). Leads are embedded in frame. The leads are exposed within the frame to allow connection to a semiconductor device or passive device mounted on the die attach pad, and exposed on the external surface of the frame to allow connection to a conductor external to the frame. Each of the leads embedded in the frame may be up-turned or down-turned for electrically connecting to a different pre-molded lead frame in the stack or other conductor. The die attach pads of the pre-molded lead frames at the top and/or bottom of the stack may be exposed to provide efficient heat transfer. The stack of pre-molded lead frames is encapsulated by molding compound to form a unitary package.

The stacked pre-molded lead frames that package a semiconductor device are referred to herein as a base pre-molded lead frame, an intermediate pre-molded lead frame, and a cap pre-molded lead frame. A base pre-molded lead frame is disposed at the bottom of a stack and includes leads for connecting the package to a substrate, such as a printed circuit board. A cap pre-molded lead frame is disposed at the top of a stack and includes leads for connecting to base pre-molded lead frame or an intermediate pre-molded lead frame. An intermediate pre-molded lead frame is disposed between two other pre-molded lead frames in the interior of the stack, and includes leads for connecting to a pre-molded lead frame on either side. For example, an intermediate pre-molded lead frame may be disposed between a base pre-molded lead frame and a cap pre-molded lead frame, and include leads for connecting to both the base pre-molded lead frame and the cap pre-molded lead frame.

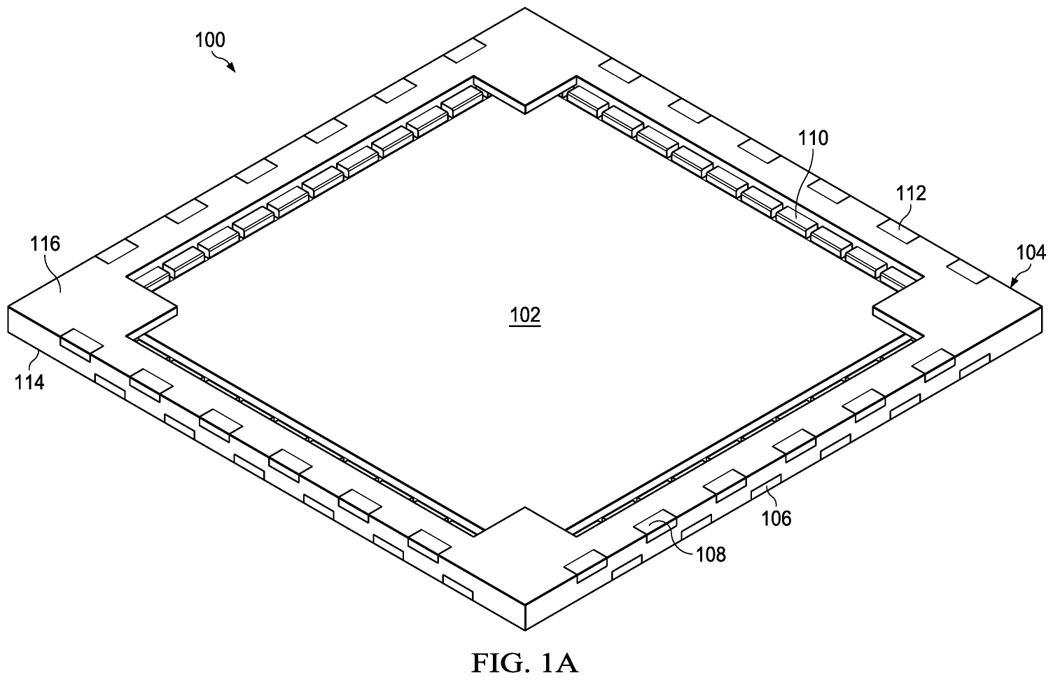

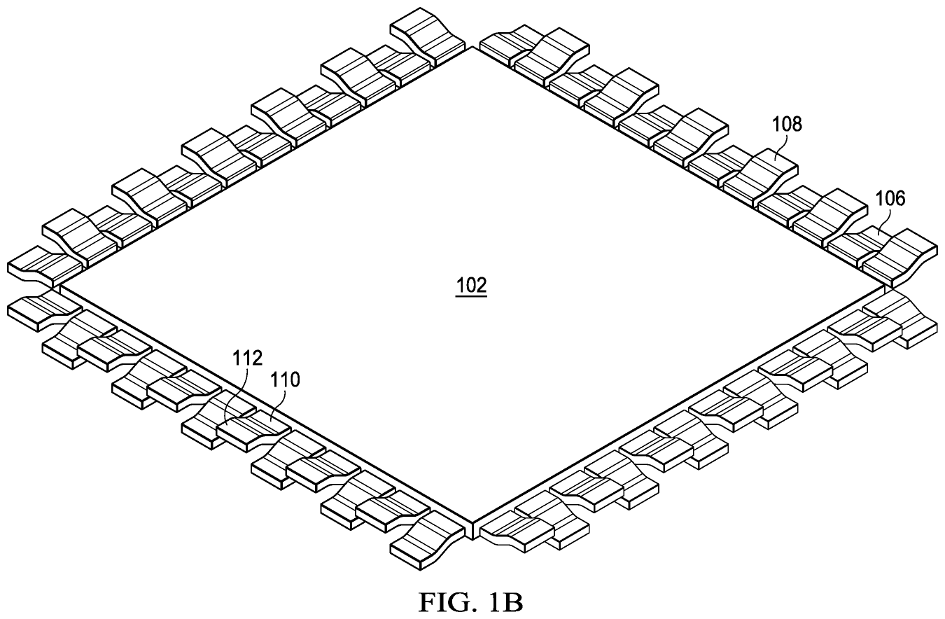

FIGS. 1A and 1B show perspective views of an example base pre-molded lead frame 100 and conductive portions thereof in accordance with the present disclosure. The base pre-molded lead frame 100 includes a die attach pad 102, a frame 104 disposed around the edges of the die attach pad 102, and, embedded in the frame 104, upturned leads 108 and downturned leads 106. With respect to the base pre-molded lead frame 100, “upturned” indicates extension towards a top surface 116 of the frame 104, and “downturned” indicates extension towards a bottom surface 114 of the frame 104. The downturned leads 106 provide connections between a device mounted on the die attach pad 102 and a substrate to which the base pre-molded lead frame 100 is mounted. The upturned leads 108 provide connections between a device mounted on the die attach pad 102 and an intermediate or cap pre-molded lead frame. The die attach pad 102, the downturned leads 106, and upturned leads 108 may be formed of a conductive material, such as copper. The frame 104 may be formed of a plastic molding compound, such as an epoxy resin with filler (e.g., fused silica) and other materials.

Each of the downturned leads 106 and the upturned leads 108 includes an end 110 and an end 112. The end 110 is exposed in an area bounded by the frame 104 (i.e., within the frame 104) for connection via a bond wire to a device mounted on the die attach pad 102. The end 112 is exposed on an outer surface of the frame 104 for connection to a substrate on which the base pre-molded lead frame 100 is mounted or for connection to an intermediate or cap pre-molded lead frame. The end 112 of each of the downturned leads 106 is exposed on the bottom surface 114 of the frame 104, and the end 112 of each of the upturned leads 108 is exposed on the top surface 116 of the frame 104. The die attach pad 102 may be exposed for transfer of heat from a device mounted on the die attach pad 102 to the substrate on which the base pre-molded lead frame 100 is mounted. Accordingly, devices that dissipate substantial heat may be mounted on the die attach pad 102. The surface of the die attach pad 102 is substantially flush with the bottom surface 114 of the frame 104 in some implementations.

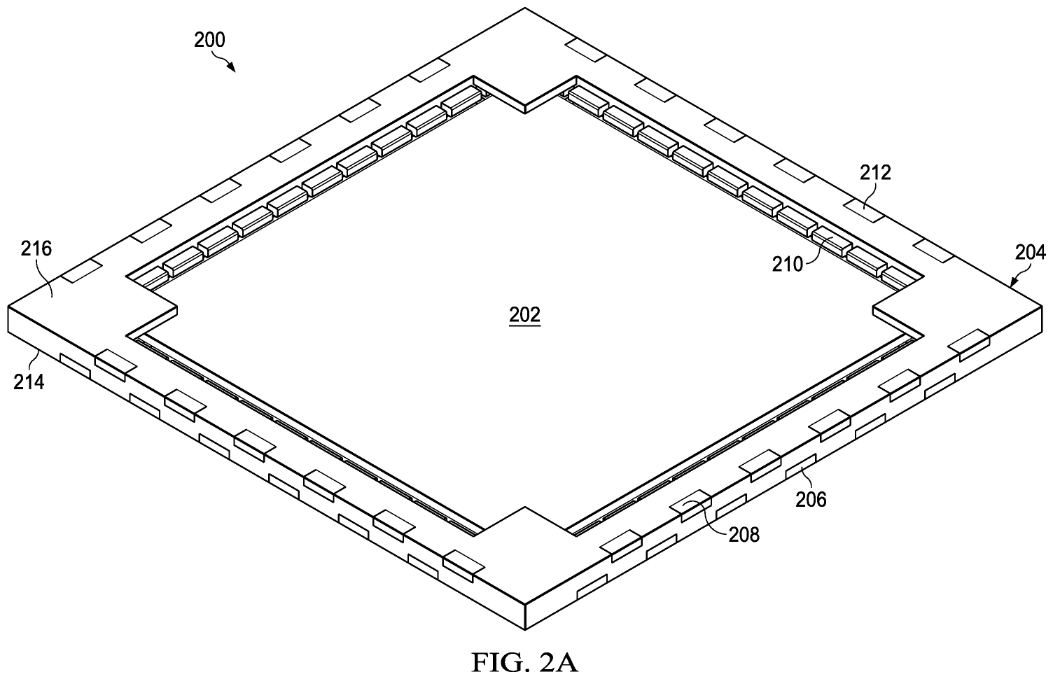

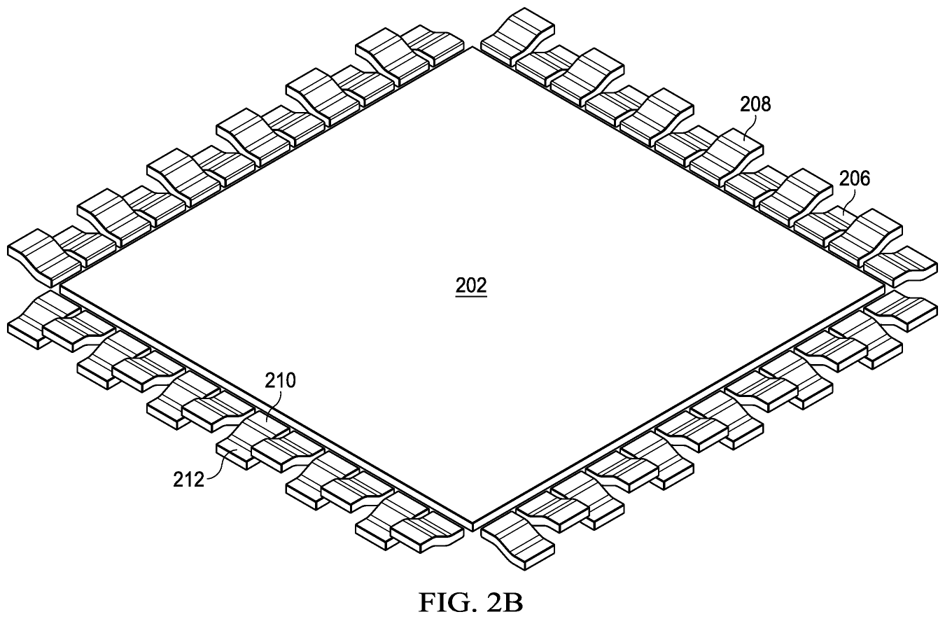

FIGS. 2A and 2B show perspective views of an example intermediate pre-molded lead frame 200 and conductive portions thereof in accordance with the present disclosure. The intermediate pre-molded lead frame 200 includes a die attach pad 202, a frame 204 disposed around the edges of the die attach pad 202, and, embedded in the frame 204, upturned leads 208 and downturned leads 206. With respect to the intermediate pre-molded lead frame 200, “upturned” indicates extension towards a top surface 216 of the frame 204, and “downturned” indicates extension towards a bottom surface 214 of the frame 204. The downturned leads 206 provide connections between a device mounted on the die attach pad 202 and a pre-molded lead frame disposed below the intermediate pre-molded lead frame 200, such as a base pre-molded lead frame 100. The upturned leads 208 provide connections between a device mounted on the die attach pad 202 and an intermediate or cap pre-molded lead frame. The die attach pad 202, the downturned leads 206, and the upturned leads 208 may be formed of a conductive material, such as copper. The frame 204 may be formed of a plastic molding compound, such as an epoxy resin with filler (e.g., fused silica) and other materials.

Each of the downturned leads 206 and the upturned leads 208 includes an end 210 and an end 212. The end 210 is exposed in an area bounded by the frame 204 (i.e., within the frame 204) for connection via a bond wire to a device mounted on the die attach pad 202. The end 212 is exposed on an outer surface of the frame 204 for connection to another pre-molded lead frame, such as a base, intermediate, or cap pre-molded lead frame. The end 212 of each of the downturned leads 206 is exposed on the bottom surface 214 of the frame 204, and the end 212 of each of the upturned leads 208 is exposed on the top surface 216 of the frame 204. For example, the end 212 of a downturned lead 206 may conductively engage an end 112 of an upturned lead 108 to provide a conductive path between the intermediate pre-molded lead frame 200 and the base pre-molded lead frame 100. Because the intermediate pre-molded lead frame 200 is sandwiched between two other pre-molded lead frames, the die attach pad 202 is not exposed for transfer of heat from a device mounted on the die attach pad 202.

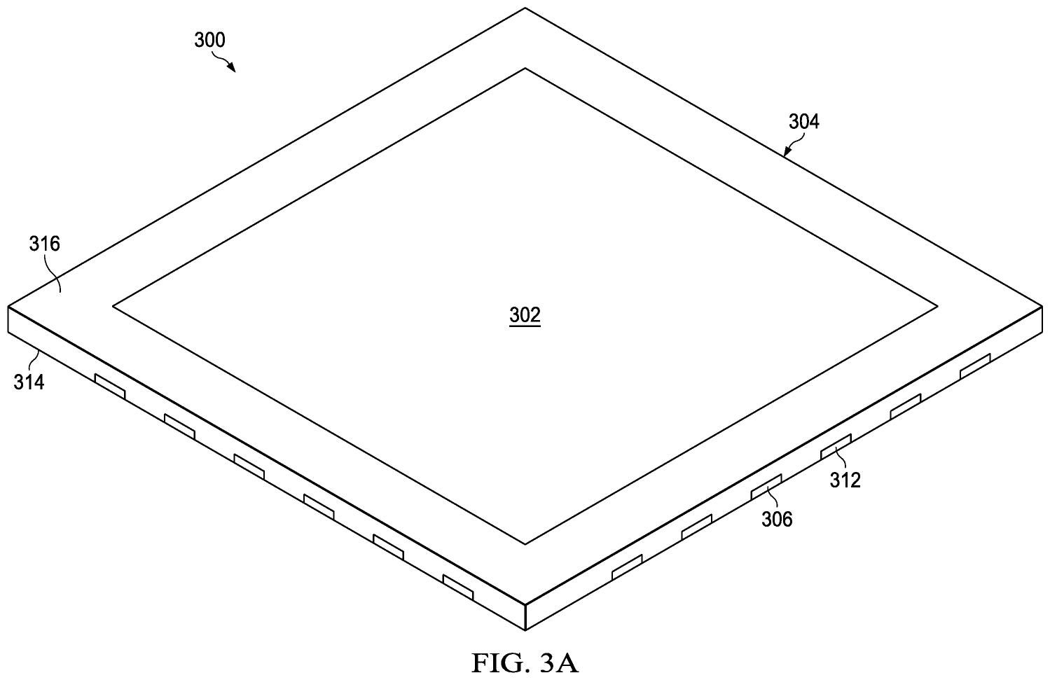

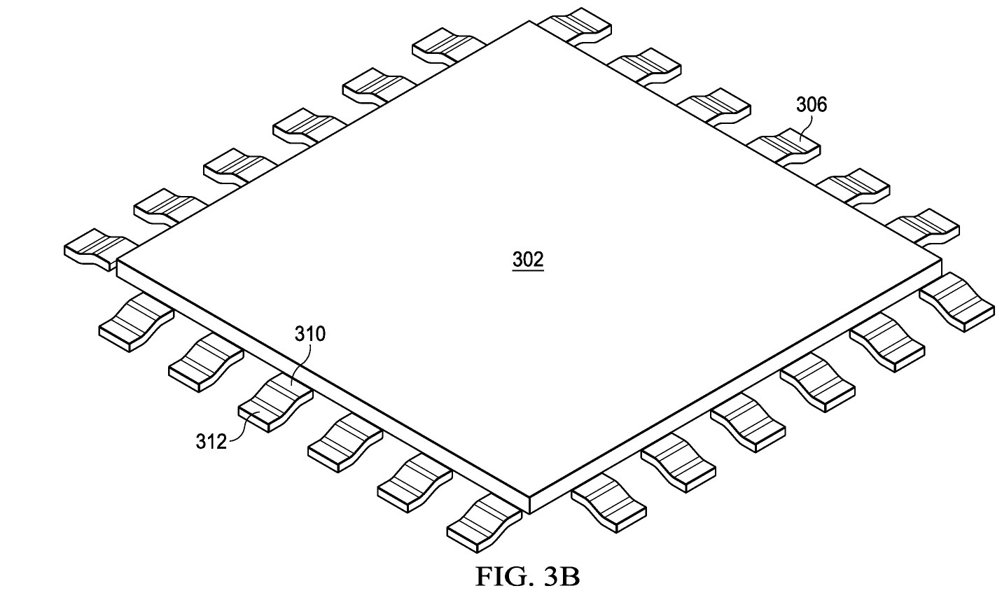

FIGS. 3A and 3B show perspective views of an example cap pre-molded lead frame 300 and conductive portions thereof in accordance with the present disclosure. The cap pre-molded lead frame 300 includes a die attach pad 302, a frame 304 disposed around the edges of the die attach pad 302, and, embedded in the frame 304, downturned leads 306. With respect to the cap pre-molded lead frame 300, “downturned” indicates extension towards a bottom surface 314 of the frame 304. The downturned leads 306 provide connections between a device mounted on the die attach pad 302 and another pre-molded lead frame. The die attach pad 302 and the downturned leads 306 may be formed of a conductive material, such as copper. The frame 304 may be formed of a plastic molding compound, such as an epoxy resin with filler (e.g., fused silica) and other materials.

Each of the downturned leads 306 includes an end 310 and an end 312. The end 310 is exposed in an area bounded by the frame 304 (i.e., within the frame 304) for connection via a bond wire to a device mounted on the die attach pad 302. The end 312 is exposed on an outer surface of the frame 304 for connection to another pre-molded lead frame, such an intermediate pre-molded lead frame 200 or a base pre-molded lead frame 100. The end 312 of each of the downturned leads 306 is exposed on a bottom surface 314 of the frame 304. For example, the end 312 of a downturned lead 306 may conductively engage an end 212 of an upturned lead 208 to provide a conductive path between the cap pre-molded lead frame 300 and the intermediate pre-molded lead frame 200. The die attach pad 302 may be exposed for transfer of heat from a device mounted on the die attach pad 302 to a heat sink mounted to the die attach pad 302 or to air about the die attach pad 302. Accordingly, devices that dissipate substantial heat may be mounted on the die attach pad 302. The surface of the die attach pad 302 is substantially flush with the top surface 316 of the frame 304 in some implementations.

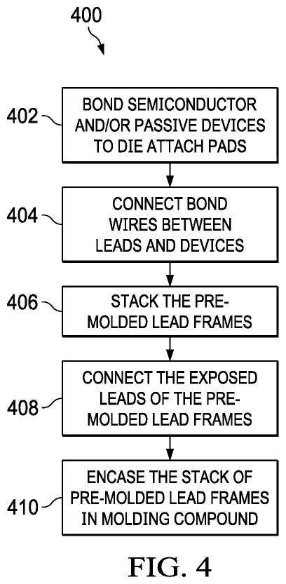

FIG. 4 shows a flow diagram for an example method 400 for packaging a semiconductor device using stacked pre-molded lead frames in accordance with the present disclosure. Though depicted sequentially as a matter of convenience, at least some of the actions shown can be performed in a different order and/or performed in parallel. Additionally, some implementations may perform only some of the actions shown.

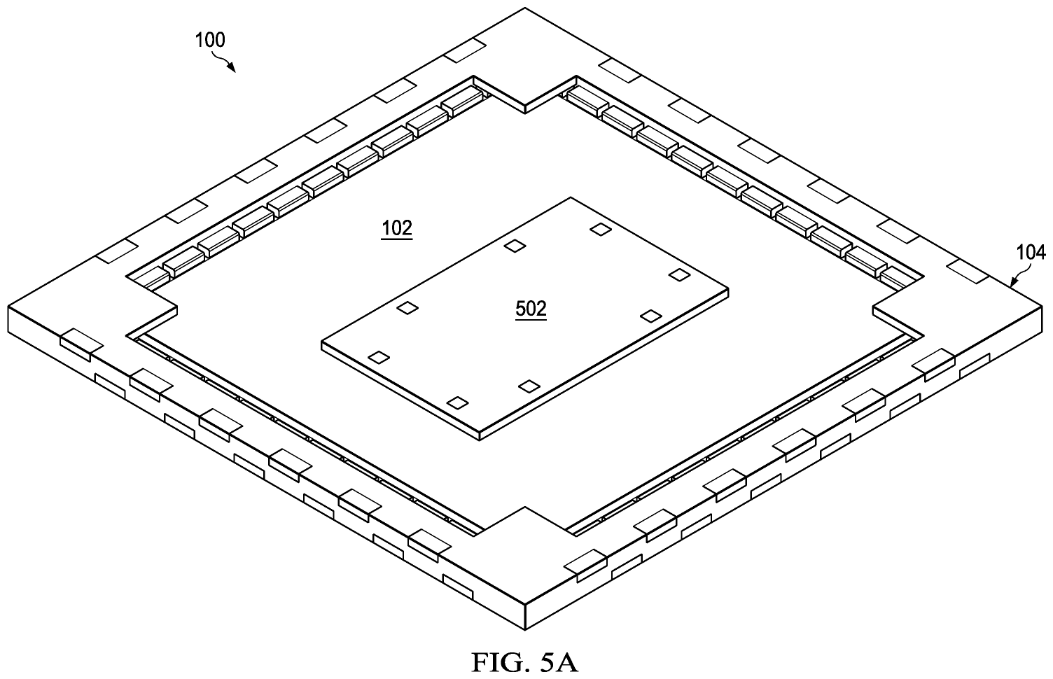

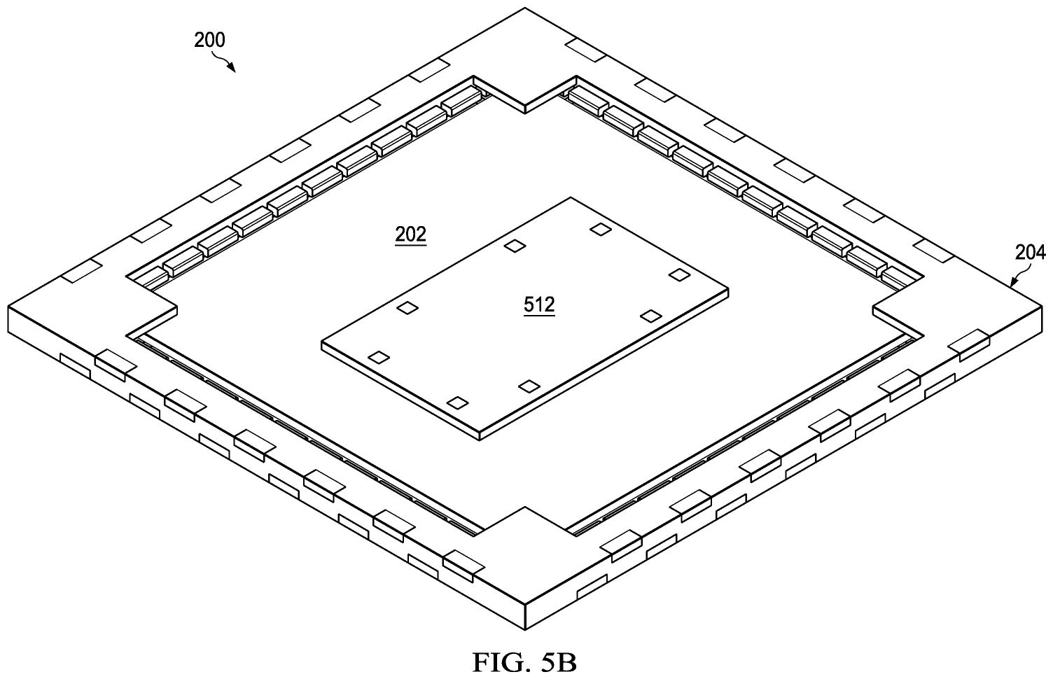

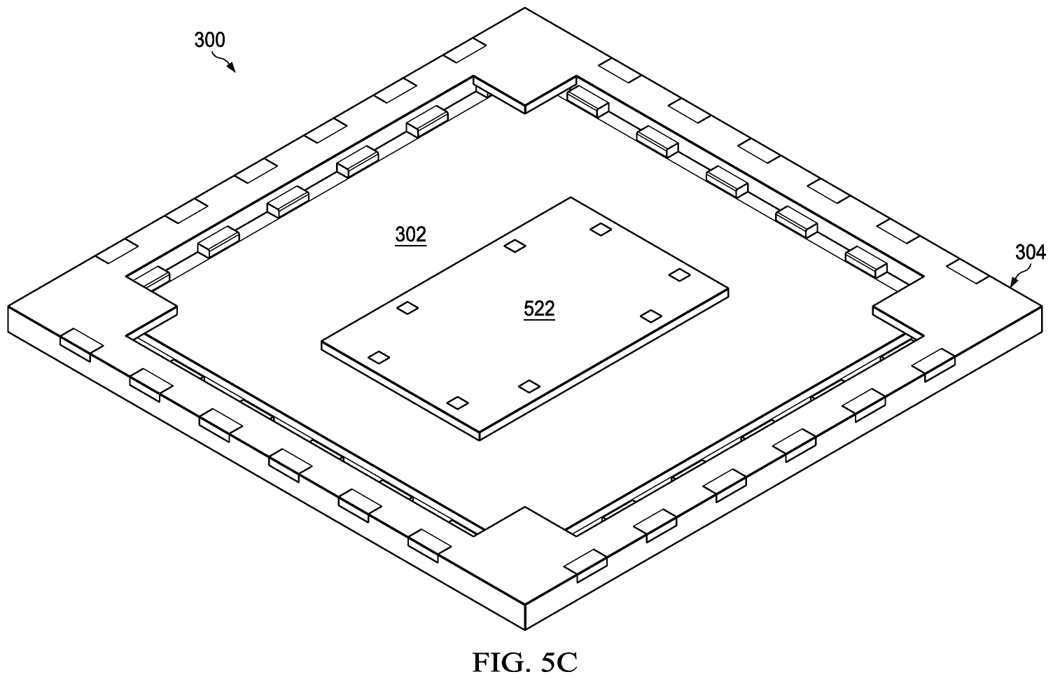

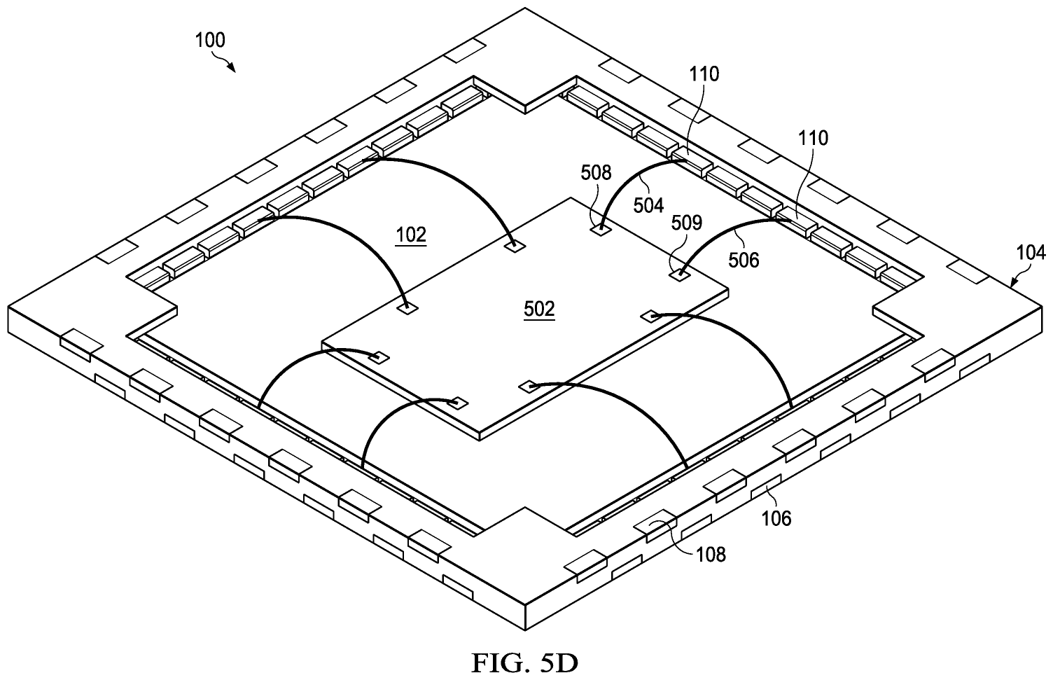

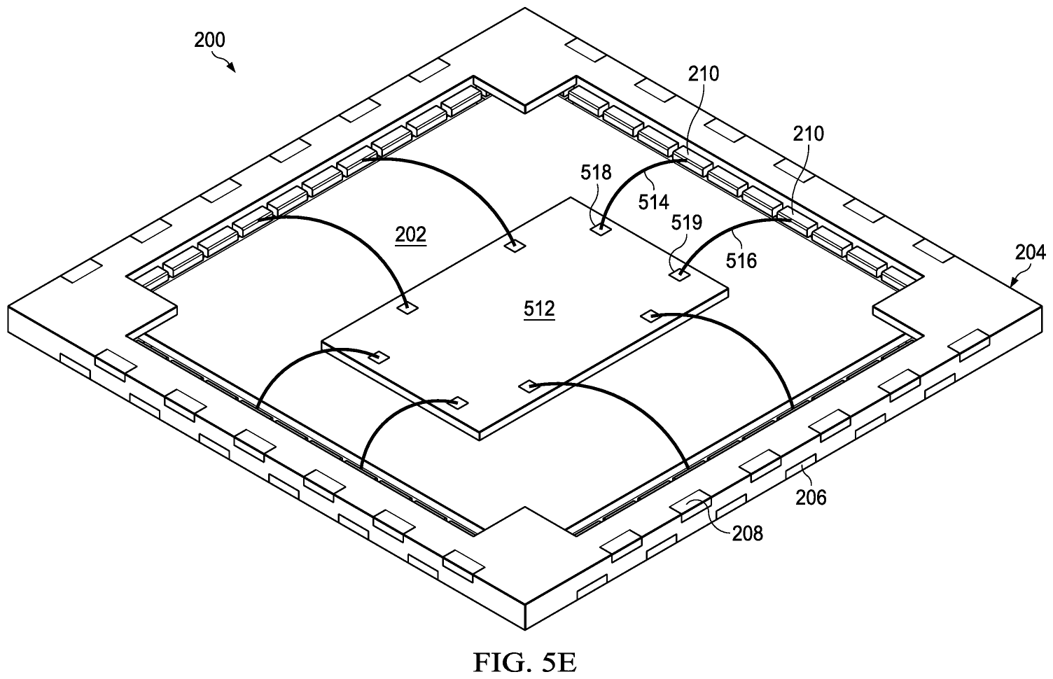

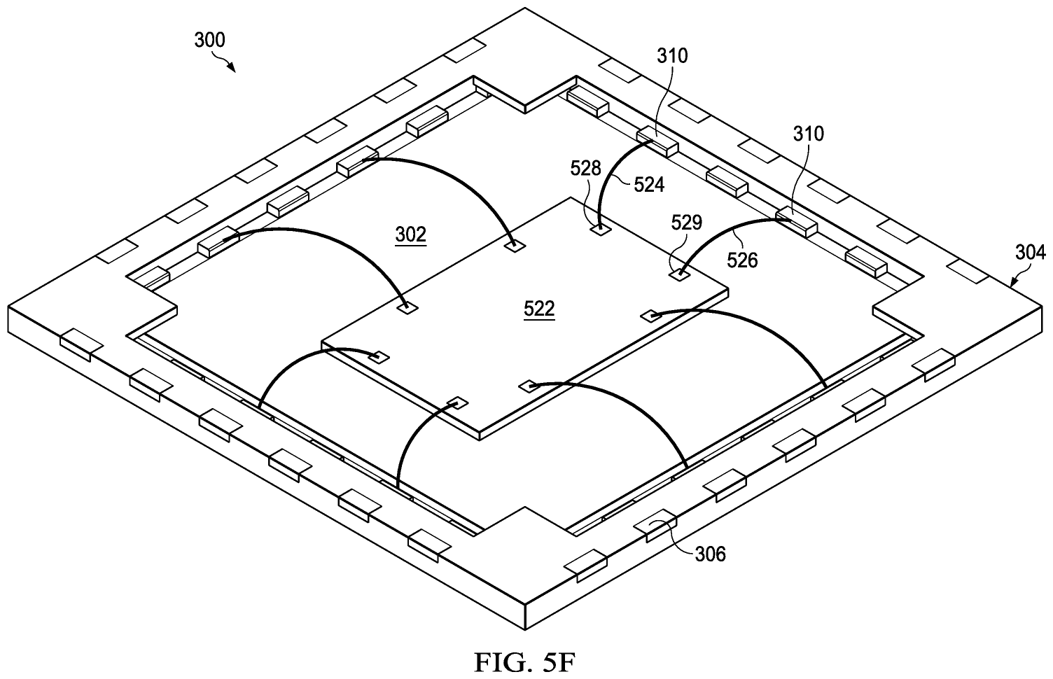

In block 402, components are bonded to the die attach pads of the pre-molded lead frames to be stacked. The components may include semiconductor devices, such as integrated circuit dies or discrete transistors, or passive devices, such as resistors, capacitors, or inductors. Components may be bonded to the die attach pads using solder, epoxy, sinter, etc. FIG. 5A shows a semiconductor device 502, such as an integrated circuit die, bonded to the die attach pad 102 of the base pre-molded lead frame 100. FIG. 5B shows a semiconductor device 512 bonded to the die attach pad 202 of the intermediate pre-molded lead frame 200. In some implementations, the die attach pad 202 may be formed to provide conductive signal routing between different components mounted on the 202. FIG. 5C shows a semiconductor device 522 bonded to the die attach pad 302 of the cap pre-molded lead frame 300.

In block 404, bond wires are added to the pre-molded lead frames to provide electrical connections between the components bonded to the die attach pads and the leads of each pre-molded lead frame. FIG. 5D shows a bond wire 504 connecting the semiconductor device 502 (e.g., a terminal 508 of the semiconductor device 502) to the end 110 of a downturned lead 106, and a bond wire 506 connecting the semiconductor device 502 (e.g., a terminal 509 of the semiconductor device 502) to the end 110 of an upturned lead 108. FIG. 5E shows a bond wire 514 connecting the semiconductor device 512 (e.g., a terminal 518 of the semiconductor device 512) to the end 210 of a downturned lead 206, and a bond wire 516 connecting the semiconductor device 512 (e.g., a terminal 519 of the semiconductor device 512) to the end 210 of an upturned lead 208. FIG. 5F shows a bond wire 524 connecting the semiconductor device 522 (e.g., a terminal 528 of the semiconductor device 522) to the end 310 of a downturned lead 306, and a bond wire 526 connecting the semiconductor device 522 (e.g., a terminal 529 of the semiconductor device 522) to the end 310 of a downturned lead 306.

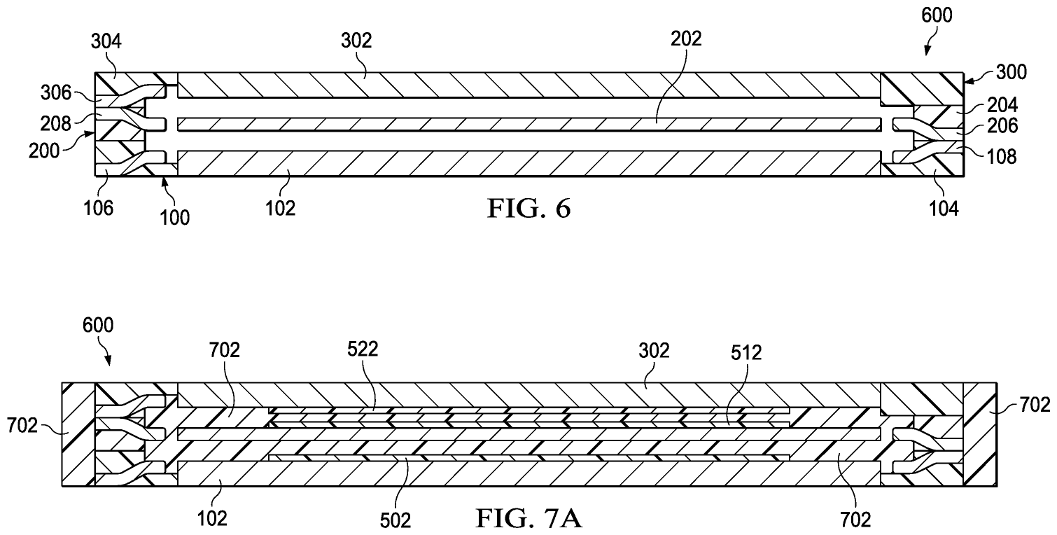

In block 406, the pre-molded lead frames, including components and wire bonds, are stacked. FIG. 6 shows a cross-section view of an example stack 600 of pre-molded lead frames. While FIG. 6 shows a stack 600 that includes three pre-molded lead frames, various implementations of the stack 600 may include two or more stacked pre-molded lead frames. For example, an implementation of the stack 600 may include only a base pre-molded lead frame and a cap pre-molded lead frame, or an implementation of the stack 600 may include multiple intermediate pre-molded lead frames in addition to the base pre-molded lead frame and the cap pre-molded lead frame. In the stack 600, the upturned leads 108 of the base pre-molded lead frame 100 conductively engage the downturned leads 206 of the intermediate pre-molded lead frame 200, and the upturned leads 208 of the intermediate pre-molded lead frame 200 conductively engage the downturned leads 306 of the cap pre-molded lead frame 300. The die attach pad 102 is exposed on the bottom of the stack 600, and the die attach pad 302 is exposed on the top of the stack 600.

In block 408, the conductively engaged leads of the stacked pre-molded lead frames are connected and bonded. For example, solder paste added to the end 110 of the upturned leads 108 or the end 210 of the downturned leads 206 may be reflowed, conductive epoxy or sintering applied to the engaged leads 108, 206, 208, and 306.

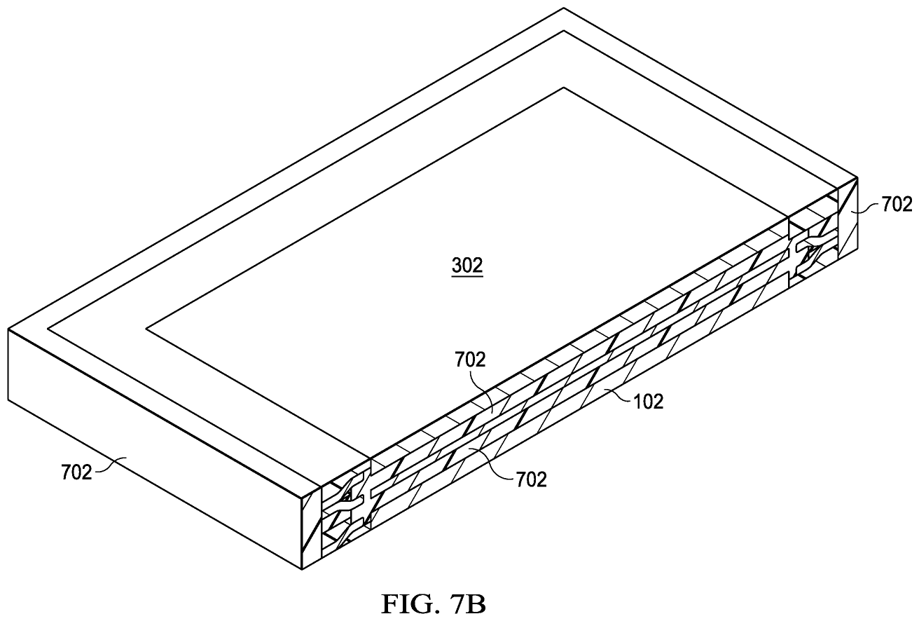

In block 410, the stack 600 is placed in a transfer mold and encased in molding compound. FIGS. 7A and 7B show cross-section views of the stack 600 of pre-molded lead frames with molding compound 702 encasing the pre-molded lead frames. The molding compound 702 fills the internal cavities of the pre-molded lead frame stack, covers the sides of the frame 104, frame 204, and frame 304, and leaves the die attach pad 102 and the die attach pad 302 exposed for efficient heat transfer. The molding compound 702 may be a plastic molding compound, such as an epoxy resin with filler (e.g., fused silica) and other materials.

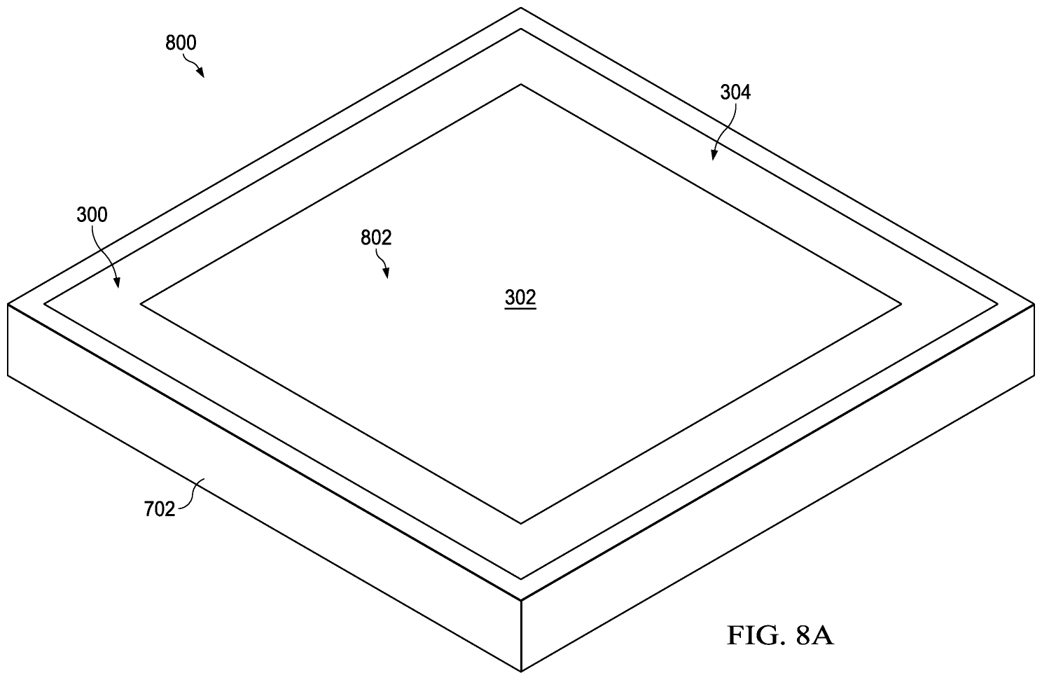

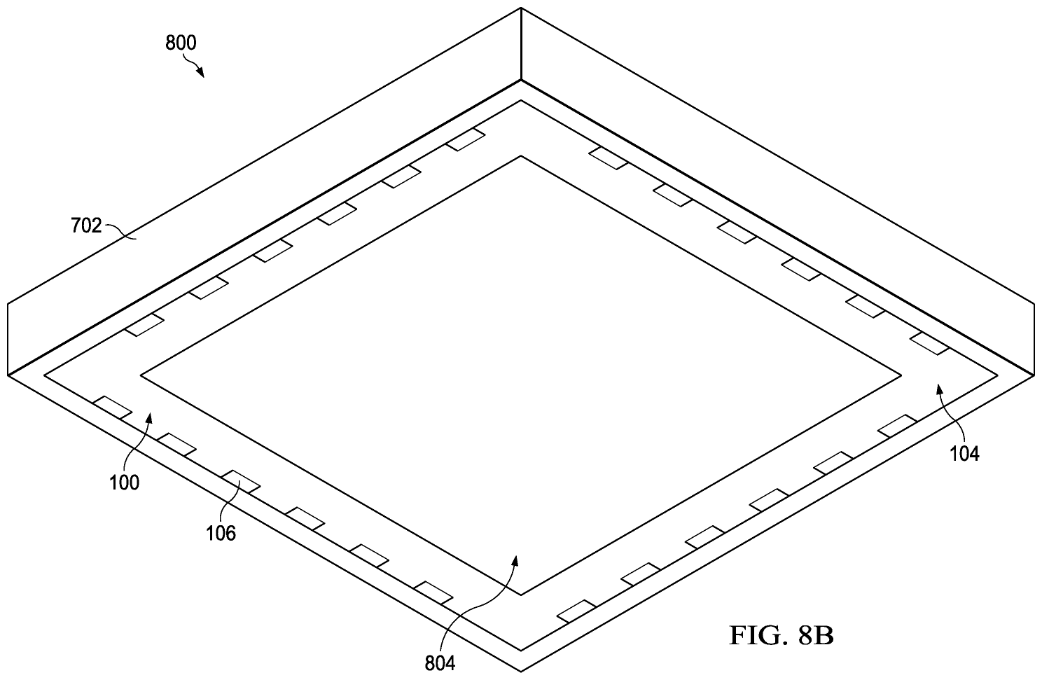

FIGS. 8A and 8B show perspective views of the top and bottom of an integrated circuit package 800 formed of stacked pre-molded lead frames in accordance with the present disclosure. In the integrated circuit package 800, the die attach pad 302 is exposed on the top 802 of the integrated circuit package 800, and the die attach pad 102 is exposed on the bottom 804 of the 800 to transfer heat from the components bonded to the die attach pad 302 and the die attach pad 102. The downturned leads 106 are exposed on the bottom 804 of the integrated circuit package 800 for connecting the integrated circuit package 800 to a substrate, such as a printed circuit board.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. An integrated circuit package, comprising:
a pre-molded lead frame, comprising:
a die attach pad;
a frame, formed of an encapsulation material, bordering an edge of the die attach pad;
a first lead embedded in the frame, the first lead comprising:
a first end exposed at an interior surface of the frame;
a second end exposed at first exterior surface of the frame;
a second lead embedded in the frame, the second lead comprising:
a first end exposed at the interior surface of the frame;
a second end exposed at a second exterior surface of the frame,
wherein the second exterior surface is opposite the first exterior surface;
a semiconductor device bonded to the die attach pad;
a first bond wire connectively coupling the semiconductor device to the first end of the first lead of the pre-molded lead frame; and
a second bond wire connectively coupling the semiconductor device to the first end of the second lead of the pre-molded lead frame.

2. The integrated circuit package of claim 1, wherein the pre-molded lead frame is a first pre-molded lead frame, and the integrated circuit package further comprises:
a second pre-molded lead frame stacked with the first pre-molded lead frame, the second pre-molded lead frame comprising:
a die attach pad;
a frame, formed of an encapsulation material, bordering an edge of the die attach pad of the second pre-molded lead frame;
a lead embedded in the frame of the second pre-molded lead frame, the lead comprising:
a first end exposed at an interior surface of the frame of the second pre-molded lead frame;
a second end exposed at a first exterior surface of the frame of the second pre-molded lead frame; wherein the first exterior surface of the frame of the second pre-molded lead frame faces the second exterior surface of the frame of the first pre-molded lead frame.

3. The integrated circuit package of claim 2, wherein the second end of the lead of the second pre-molded lead frame conductively engages the second end of the second lead of the first pre-molded lead frame.

4. The integrated circuit package of claim 2, further comprising a third pre-molded lead frame stacked between the first pre-molded lead frame and the second pre-molded lead frame, the third pre-molded lead frame comprising:
a die attach pad;
a frame, formed of an encapsulation material, bordering an edge of the die attach pad;
a first lead embedded in the frame of the third pre-molded lead frame, the first lead comprising:
a first end exposed at an interior surface of the frame of the third pre-molded lead frame; and
a second end exposed at a first exterior surface of the frame of the third pre-molded lead frame;
a second lead embedded in the frame of the third pre-molded lead frame, the second lead comprising:
a first end exposed at an interior surface of the frame of the third pre-molded lead frame; and
a second end exposed at a second exterior surface of the frame of the third pre-molded lead frame; wherein the second exterior surface of the frame of the third pre-molded lead frame is opposite the first exterior surface of the frame of the third pre-molded lead frame.

5. The integrated circuit package of claim 4, wherein:
the second end of the lead of the second pre-molded lead frame conductively engages the second end of the second lead of the third pre-molded lead frame; and
the second end of the second lead of the first pre-molded lead frame conductively engages the second end of the second lead of the third pre-molded lead frame.

6. The integrated circuit package of claim 2, further comprising:
a second semiconductor device bonded to the die attach pad of the second pre-molded lead frame; and
a third bond wire connectively coupling the second semiconductor device to the first end of the lead of the second pre-molded lead frame.

7. The integrated circuit package of claim 2, further comprising molding compound that encases the frame of the first pre-molded lead frame and the frame of the second pre-molded lead frame.

8. The integrated circuit package of claim 2, wherein the die attach pad of the first pre-molded lead frame is exposed on a first side of the integrated circuit package, and the die attach pad of the second pre-molded lead frame is exposed on a second side of the integrated circuit package, wherein the first side of the integrated circuit package is opposite the second side of the integrated circuit package.

9. A method for fabricating a semiconductor package, comprising:
disposing a first pre-molded lead frame in a stack with a second pre-molded lead frame; and
engaging an upturned lead of the first pre-molded lead frame with a downturned lead of the second pre-molded lead frame.

10. The method of claim 9, further comprising:
bonding a first semiconductor device to a die attach pad of the first pre-molded lead frame; and
bonding a second semiconductor device to a die attach pad of the second pre-molded lead frame.

11. The method of claim 10, further comprising:
attaching a first end of a first bond wire to the first semiconductor device;
attaching a second end of the first bond wire to the upturned lead;
attaching a first end of a second bond wire to the second semiconductor device; and
attaching a second end of the second bond wire to the downturned lead.

12. The method of claim 9, further comprising:
disposing a third pre-molded lead frame in the stack with the first pre-molded lead frame and the second pre-molded lead frame;
engaging an upturned lead of the second pre-molded lead frame with a downturned lead of the third pre-molded lead frame.

13. The method of claim 12, further comprising:
bonding a first semiconductor device to a die attach pad of the third pre-molded lead frame; and
bonding a second semiconductor device to a die attach pad of the second pre-molded lead frame.

14. The method of claim 13, further comprising:
attaching a first end of a first bond wire to the third semiconductor device;
attaching a second end of the first bond wire to the downturned lead;
attaching a first end of a second bond wire to the second semiconductor device; and
attaching a second end of the second bond wire to the upturned lead.

15. The method of claim 9, further comprising applying mold compound to the first pre-molded lead frame and the second pre-molded lead frame subsequent to the engaging.

16. The method of claim 9, further comprising engaging a downturned lead of the first pre-molded lead frame and conductive pad of a substrate on which the semiconductor package is mounted.

17. An integrated circuit package, comprising:
a first semiconductor device;
a first pre-molded lead frame, comprising:
a die attach pad bonded to the first semiconductor device;
a frame, formed of an encapsulation material, bordering an edge of the die attach pad;
an upturned lead embedded in the frame, and conductively coupled to the first semiconductor device; and
a downturned lead embedded in the frame, and conductively coupled to the first semiconductor device;
a second semiconductor device;
a second pre-molded lead frame stacked with the first pre-molded lead frame, comprising:
a die attach pad bonded to the second semiconductor device;
a frame, formed of an encapsulation material, bordering an edge of the die attach pad of the second pre-molded lead frame;
an upturned lead embedded in the frame of the second pre-molded lead frame, and conductively coupled to the second semiconductor device; and
a downturned lead embedded in the frame of the second pre-molded lead frame and conductively engaged with the upturned lead of the first pre-molded lead frame, and conductively coupled to the second semiconductor device;
a third semiconductor device; and
a third pre-molded lead frame stacked with the first pre-molded lead frame and the second pre-molded lead frame, comprising:
a die attach pad bonded to the third semiconductor device;
a frame, formed of an encapsulation material, bordering an edge of the die attach pad of the third pre-molded lead frame; and
a downturned lead embedded in the frame of the third pre-molded lead frame, conductively coupled to the third semiconductor device, and conductively engaged with the upturned lead of the second pre-molded lead frame.

18. The integrated circuit package of claim 17, wherein the downturned lead of the first lead frame conductively engages a substrate on which the integrated circuit package is mounted.

19. The integrated circuit package of claim 17, further comprising molding compound that encases the frame of the first pre-molded lead frame, the frame of the second pre-molded lead frame, and the frame of the third pre-molded lead frame.

20. The integrated circuit package of claim 17, wherein the die attach pad of the first pre-molded lead frame is exposed on a first side of the integrated circuit package, and the die attach pad of the third pre-molded lead frame is exposed on a second side of the integrated circuit package, wherein the first side of the integrated circuit package is opposite the second side of the integrated circuit package.
